(19) United States
(12) Patent Application Publication
(10) Pub. No.: US 2026/0076156 A1
(43) Pub. Date: Mar. 12, 2026

(54) MICRO-TRANSFER PRINTING OF THIN FILMS

(71) Applicants: UNIVERSITEIT GENT, GENT (BE); IMEC VZW, Leuven (BE)

(72) Inventors: Tom VANDEKERCKHOVE, GENT (BE); Tom VANACKERE, GENT (BE); Gunther ROELKENS, GENT (BE); Stéphane CLEMMEN, GENT (BE); Bart KUYKEN, GENT (BE)

(21) Appl. No.: 19/105,953

(22) PCT Filed: Aug. 21, 2023
(86) PCT No.: PCT/EP2023/072893

§ 371 Date: Feb. 24, 2025

(30) Foreign Application Priority Data
Aug. 22, 2022 (EP) 22191451.8

(51) Int. Cl. H01L 21/78; H01L 21/683

(52) U.S. Cl. CPC H10P 95/11; H10P 72/74

(57) ABSTRACT

A method for forming a device coupon (100) includes providing a source wafer (1) with a source substrate (10); a sacrificial layer (11); and a film (12). At least one device coupon (100) is formed in the film (12). One or more designed breakable tethers is designed to secure the device coupon (100) to the film (12). The method includes etching one or more recesses (111) extending through the device coupon (100), thereby exposing the sacrificial layer (11); and etching the sacrificial layer (11) away at least partially through one or more of the recesses (111), thereby forming one or more sacrificial recesses (121) in the sacrificial layer (11). At least some pairs of recesses (111) and sacrificial recesses (121) are filled with a support material (200), thereby forming support structures (220) for device coupon (100).

### TECHNICAL FIELD

The present invention generally relates, amongst others, to a source wafer and to a method of micro-transfer printing. More particularly, it relates to a source wafer comprising a thin film for heterogeneous integration through micro-transfer printing for integrated photonics systems and/or integrated electronics systems, and to a method for manufacturing robust and reliable transfer printed, e.g., micro-transfer printed, electronic systems.

### BACKGROUND

Silicon and silicon nitride passive photonic platforms have shown impressive developments, offering low-cost, mass-manufacturable compact optical circuits for telecommunications as well as other industrial applications using for example CMOS compatible fabrication techniques. However, for most applications, the material properties of these platforms by themselves do not suffice for the envisioned applications, such as for example the creation of high-performant light sources, detectors and modulators.

One popular method allowing the heterogeneous integration of other materials on the existing photonic platforms is micro-transfer printing. This pick-and-place integration process relies on the kinetically controlled adhesion of for example a stamp, such as an elastomeric stamp, to pick up devices and/or thin material films, referred to as coupons or device coupons, from a source wafer and print them on for example a photonic or electronic target wafer. For a reliable pick-up, one typically etches away a sacrificial layer under the coupon such that the coupon is suspended, only being connected to the wafer at its sides with specifically designed connections, also known as tethers. During the pick-up, these break in a controlled way, releasing them from the source wafer and followed by the printing of these coupons on the target wafer.

The ability to suspend the coupon depends on its mechanical properties, where stiffness is one of the critical factors. While typical coupons are often multiple microns thick, giving a width-to-thickness aspect ratio on the order of 20, the micro-transfer printing of thin material films involves thicknesses for the coupons ranging from a nanometer to a few hundred nanometers. Nonetheless, certain applications still need surface areas to be printed with dimensions of hundreds of micrometers long and wide. In these cases, the aspect ratio can very easily exceed 1000.

A reduction in thickness implies a significant increase in flexibility of the thin film. This makes the process of suspending the films much more challenging as they typically collapse onto the substrate of the source wafer. Consequently, the adhesion between the coupon and the substrate of the source wafer is substantially higher due to the increased contact area, resulting in the inability to actually pick up the coupons reliably from the source wafer. While the coupons may still be sporadically pickable, the added adhesion often causes breaking of the device or film on the source wafer during pick-up. Generally, this inhibits a reliable high yield for the transfer-printing of thin films.

### SUMMARY

It is thus an object of embodiments of the present invention to propose a source wafer and a manufacturing method thereof which do not show the inherent shortcomings of the prior art. More specifically, it is an object of embodiments of the present invention to propose a source wafer and a method for micro-transfer printing with improved robustness and reliability, thereby increasing the yield of the micro-transfer printing process.

The scope of protection sought for various embodiments of the invention is set out by the independent claims.

The embodiments and features described in this specification that do not fall within the scope of the independent claims, if any, are to be interpreted as examples useful for understanding various embodiments of the invention.

There is a need for a source wafer which demonstrates improved robustness, with coupons which do not collapse on the source wafer, thereby allowing their reliable pick-up from the source wafer and a high yield for the transfer printing process, more particularly for the transfer printing process of thin films. Additionally, there is a need for a method of forming a device coupon with improved robustness.

There is a need for a method for heterogeneously integrating a device coupon onto a target wafer via micro-transfer printing, wherein the method allows a reliable pick-up from the source wafer and achieves a high yield for the transfer printing process. Finally, there is a need for a device manufactured using the method for heterogeneously integrating a device coupon onto a target wafer via micro-transfer printing.

This object is achieved, according to a first example aspect of the present disclosure, by a method for forming a device coupon for heterogeneous integration through micro-transfer printing for integrated photonics systems and/or integrated electronics systems, the method comprising the steps of:
providing a source wafer comprising:
   a source substrate;
   a sacrificial layer on top of the source substrate; and
   a film on top of the sacrificial layer;
forming at least one device coupon in the film, wherein a device coupon is delimited by a periphery;
designing one or more designed breakable tethers at the periphery, the designed breakable tethers being configured to secure the device coupon to the film;
etching one or more recesses in the device coupon, the recesses extending through the device coupon, thereby exposing the sacrificial layer;
partially etching the sacrificial layer away at least through one or more of the recesses, thereby forming one or more sacrificial recesses in the sacrificial layer between the device coupon and the source substrate; and
filling at least some pairs of recesses and sacrificial recesses with a support material, thereby forming support structures for the device coupon in the device coupon and in the sacrificial layer.

With the method according to the present disclosure, a reliable high-yield heterogeneous integration of for example very flexible material thin films via micro-transfer printing is achieved. The present disclosure consists of a method that allows for suspending very thin films on source wafers, while keeping the large surface area that needs to be printed on a target wafer. With the method according to the present disclosure, a device coupon is formed, which can for example demonstrate an aspect ratio of the device coupon for example exceeding 1000. Indeed, while the aspect ratio of the full device coupon still exceeds for example 1000, by forming support structures in the device coupon and under the device coupon which act like support pillars for the device coupon, the effective aspect ratio that matters for suspension of the device coupon is reduced significantly. Consequently, with the method according to the present disclosure, it is much less challenging to suspend the device coupon, which leads to a high yield for the transfer-printing process. In other words, the support structures formed in the device coupon and under the device coupon formed by the method according to the present disclosure increase the robustness of the device coupon. With the method for forming a device coupon according to the present disclosure, particularly thanks to the support structures formed in the device coupon and under the device coupon, the adhesion between the device coupon and the source substrate of the source wafer is minimized, resulting in the ability to pick up the device coupon reliably from the source wafer. With the method according to the present disclosure, the device coupon does not break when the device coupon is picked up from the source wafer, thereby reaching a reliable high yield for the transfer-printing of device coupons, such as for example of thin films. Finally, the method according to the present disclosure allows changing the shape and/or the surface area of the device coupon without having to redevelop a process flow for forming and suspending the device coupon.

Prior art approaches for the heterogeneous integration on integrated photonic platforms through micro-transfer printing typically work with a much lower width-to-thickness aspect ratio for the device coupon, often due to the use of much thicker layer stacks to form the device coupons. In that case, the stiffness of the device coupon is high enough for it to be suspended through connections on the side of the device, known as the breakable tethers. The same method cannot be used reliably for example for thin films, due to the flexibility of such films, leading to the collapse of the device coupon onto the source substrate after under etch of the sacrificial layer. With micro-transfer printing methods known from the prior art, it is possible to artificially thicken the device coupon with one or more additional material layers, solely for a larger stiffness of the device coupon, but there are very often limits to how much material can be added, as well as their selective removal which translates into an upper limit of the aspect ratio for the device coupon which can be suspended. For example, doubling the surface area of the device coupon becomes problematic with methods known from the prior art, in contrast to the method according to the present disclosure, where only one or more additional support structures must be added.

With micro-transfer printing methods known from the prior art, the collapse of a device coupon formed in for example a thin film is often attributed to the capillary effects while the source wafer is drying, when etched with an etchant in the liquid phase. The surface tension of the disappearing etchant liquid puts enough force on the device coupon to cause its collapse on the source wafer. This is for example a well-known problem when suspending micro-electromechanical systems, also known as MEMS. A first possible prior art solution to this problem is to use an etchant in the vapor phase, but with materials such as lithium niobate or gallium phosphide, this gives problems due to the redeposition of etching products onto the device coupon and the source wafer. Another prior art solution is to use a process called Critical Point Drying, also known as CPD. The disruptive transition from the liquid to the gas-phase is avoided by going around the critical point by controlling the temperature and pressure of the liquid used for etching. Nevertheless, this only works up to a certain aspect ratio for the device coupon, which can be an order of magnitude smaller than what is needed, for instance to transfer a thin film over a silicon nitride ring resonator. For MEMS devices, this prior art method is typically sufficient, as the to-be-suspended surface area is kept limited and therefore the aspect ratio is sufficiently small. Additionally, MEMS devices normally work with stiff materials, which eases the suspension process. However, this prior art method is not a solution for suspending the device coupon on the source wafer, and therefore for the micro-transfer printing of for example large surface areas of thin flexible films.

On the contrary, the method according to the present disclosure can be seen as a prepping method for device coupons which are for example made of very flexible materials with for example large surface areas, resulting in a high transfer-printing yield for their heterogeneous integration on photonic and electronic integrated circuits. Indeed, by placing support structures, such as pillar-like support structures, through the device coupons and under the device coupons, these device coupons no longer need to be suspended from side to side above the source wafer, but the device coupons are suspended from support structure to support structure on the source wafer. This distance to be suspended can be made much smaller by reducing a distance between two adjacent support structures, thereby significantly decreasing the effective aspect ratio. In contrast to prior art solutions which require a re-optimization of the whole layer stack without a guaranteed success, with the method according to the present disclosure, there is no new optimization of the stiffness of the device coupon required when substantially changing the surface area or coupon shape in general, as it only comes down to optimizing a position of the support structures. For that reason, the method according to the present disclosure shows a lot of potential for systems where the footprint cannot be reduced, such as for example ring resonators-limited by the bend radius, spirals or electro-optic modulators.

In the context of the present disclosure, a recess extends through the device coupon. A recess is a hole in the device coupon, i.e. a recess extends through the total thickness of the device coupon. In other words, a recess is hollow and extends between a projection of the shape of the recess in a plane comprising the surface of the device coupon facing away from the interface between the film and the sacrificial layer, i.e. a top surface of the device coupon, and a projection of the shape of the recess in a plane comprising the interface between the film and the sacrificial layer, i.e. the bottom surface of the device coupon. This way, the recess extends completely through the thickness of the device coupon. Alternatively, only one or more regions of the recess extend entirely through the thickness of the device coupon, while one or more other regions of the recess extend partially through the thickness of the device coupon, for example through at least 50% of the thickness of the device coupon. In other words, in this alternative embodiment, the recess is partially hollow and extends between a projection of the shape of the recess in a plane comprising the surface of the device coupon facing away from the interface between the film and the sacrificial layer and a projection of the shape of the recess in a plane comprising the interface between the film and the sacrificial layer. This way, the recess extends partially through the thickness of the device coupon.

In the context of the present disclosure, a sacrificial recess extends partially through the sacrificial layer. A sacrificial recess extends between a projection of the shape of the sacrificial recess in a plane comprising the surface of the device coupon at the interface between the film and the sacrificial layer and a plane parallel to and positioned above a projection of the shape of the sacrificial recess in a plane comprising the interface between the sacrificial layer and the source substrate. Alternatively, a sacrificial recess extends completely through the sacrificial layer. A sacrificial recess is a hole in the sacrificial layer, i.e. a sacrificial recess extends through the total thickness of the sacrificial layer. In other words, a sacrificial recess is hollow and extends between a projection of the shape of the sacrificial recess in a plane comprising the surface of the device coupon at the interface between the film and the sacrificial layer and a projection of the shape of the sacrificial recess in a plane comprising the interface between the sacrificial layer and the source substrate. This way, the sacrificial recess extends completely through the thickness of the sacrificial layer. Alternatively, only one or more regions of the sacrificial recess extend entirely through the thickness of the sacrificial layer, while one or more other regions of the sacrificial recess extend partially through the thickness of the sacrificial layer, for example through at least 50% of the thickness of the sacrificial layer. In other words, in this alternative embodiment, the sacrificial recess is partially hollow and extends between a projection of the shape of the sacrificial recess in a plane at the interface between the film and the sacrificial layer and a projection of the shape of the sacrificial recess in a plane comprising the interface between the sacrificial layer and the source substrate. This way, the sacrificial recess extends partially through the thickness of the sacrificial layer.

In the context of the present disclosure, one or more support structures are formed through one or more recesses formed in the device coupon. In other words, a support structure is formed in each recess of the device coupon. Alternatively, the support structures are formed through the recesses formed in the device coupon and through the sacrificial recesses formed in the sacrificial layer, wherein the sacrificial recesses are formed below the recesses formed in the device coupon. In other words, a sacrificial recess is formed in the sacrificial layer below one or more of the recesses of the device coupon such that the sacrificial recesses are formed at a position in the sacrificial layer which is below the position of one or more of the recesses in the device coupon, thereby forming pairs of recesses and corresponding sacrificial recesses; and a support structure is formed in one or more recesses of the device coupon and in their corresponding sacrificial recesses, thereby forming a support structure in at least some pairs of recesses and sacrificial recesses. In the context of the present disclosure, a recess may have any shape, such as for example a rectangular shape, or a square shape, or a circular shape, etc. In the context of the present disclosure, a recess may have any size. In the context of the present disclosure, one or more recesses may be identical in shape and/or size and/or position on the device coupon, for example in terms of distance with respect to an edge of the device coupon. Alternatively, the recesses formed in the device coupon may all be different from each other in shape and/or size and/or position on the device coupon, for example in terms of distance with respect to an edge of the device coupon. In the context of the present disclosure, the recesses are periodically spaced in the device coupon. Alternatively, positions of the recesses in the device coupon are arbitrarily designed.

In the context of the present disclosure, a recess can have any shape, such as for example a square, a rectangle, a polygon, a disk, an ellipse, etc. In the context of the present disclosure, a sacrificial recess can have any shape, such as for example a square, a rectangle, a polygon, a disk, an ellipse, etc. Usually, a shape and a size of a recess will have an impact upon the shape of the underlying sacrificial recess.

In the context of the present invention, a support structure is understood as a structure made of support material and comprising at least two sections: a first section of support material filling a recess formed in the device coupon and a second section positioned below and coupled to the first section wherein the second section fills a sacrificial recess formed in the sacrificial layer. The support structures are formed in and underneath the device coupon before the sacrificial layer is removed or etched from under the device coupon. During the etching of the sacrificial layer, the support structures remain in between the device coupon and the source substrate, which prevents the device coupon from collapsing onto the source substrate. To manufacture the support structures underneath the device coupons, small areas, i.e. one or more recesses, are etched away in the device coupon material to be able to reach the sacrificial layer underneath the device coupon. The shape of the recesses in the device coupon does not matter, it is only important that one can access the sacrificial layer locally underneath the device coupon through one or more recesses. In case the surface area of the device coupon is small enough, the support structures can be placed on the periphery of the device coupon, without having to etch the device coupon itself.

At the locations on the device coupon where holes, i.e. recesses, are etched in the device coupon, the sacrificial layer is etched via a dry or wet etching process to enable the deposition of support material in the holes and underneath the device coupon. For example, the sacrificial layer is wet etched with HF or HCl. The etching of the sacrificial layer is a partial etch through the sacrificial layer. Some sacrificial layer remains on the source wafer between the sacrificial recess and the source substrate.

At least some recesses and corresponding sacrificial recesses formed in the sacrificial layer are to be filled with the support material. It may be useful to keep some recesses unfilled, as these recesses formed in the device coupon but not filled with support material then act as etching holes for the sacrificial layer, wherein the etchant of the sacrificial layer can reach the sacrificial layer during the release of the device coupon from the source wafer, thereby reducing the required etching time for a full release of the device coupon from the source wafer.

In the context of the present disclosure, it is important that the support structures are made of a support material which is resistant enough to the dry or wet etch of the sacrificial layer which releases the device coupon from the source wafer.

A device coupon formed by the method according to the present disclosure may be transferred to a target wafer using a stamp which picks up the device coupon and prints the device coupon onto the target wafer. Alternatively, a device coupon formed by the method according to the present disclosure may be transferred to a target wafer via a different method than using a stamp for micro-transfer printing, e.g., using the tip of a scanning electron microscope.

In the context of the present disclosure, a film and/or a device coupon comprise one or more constituent layers. The device coupon is embedded in a portion of the film acting as a support layer for the device coupon. The device coupon according to the present disclosure can have any shape in projection on a plane comprising the film and parallel to the interface between the film and the source substrate, for example a square, a rectangle, a polygon, a circle, an ellipse, etc.

In the context of the present disclosure, the film may comprise one or more device coupons. In the context of the present disclosure, a periphery of the device coupon corresponds to the edge of the device coupon. Each device coupon is delimited in the film by a respective periphery. A periphery corresponds to the outer limit or edge of a device coupon. In other words, the periphery of the device corresponds to the outermost boundary of the device coupon. The periphery of the device coupon is to be understood in the context of the present disclosure as the surface which corresponds to the sidewall boundary of the device coupon surrounding the device coupon. The periphery of the source wafer according to the present disclosure can have any shape, for example a square, a rectangle, a polygon, a disk, an ellipse, etc. The periphery may be a lateral one, i.e. one across the plane of the source substrate.

According to example embodiments, a thickness of the film is lower than 5 μm.

In the context of the present disclosure, the film is for example a thin film, i.e. a film of material which thickness is lower than 5 μm. The film for example demonstrates a higher flexibility than materials in which device coupons are typically made for micro-transfer printing. In the context of the present disclosure, flexible materials are for example, but not limited to, lithium niobate, gallium phosphide, 2D materials, thin quantum dot layers, and/or devices based on these thin films on generic integrated photonic platforms. For example, the method according to the present disclosure can be optimized for the micro-transfer printing of 300 nm lithium niobate films, as well as the micro-transfer printing of gallium phosphide films. The reliable heterogeneous integration of device coupons made out of for example very thin films with large surface areas is beneficial for many applications within the field of for example integrated photonics and integrated electronics. Thin films of lithium niobate on a silicon or silicon nitride platform are desired for example for ultrahigh-speed electro-optic modulators. Also, integration of periodically poled lithium niobate introduces a second order nonlinearity on these platforms, which already allows for example for on-chip optical parametric oscillators, also known as OPO, frequency conversion and other nonlinear applications. Furthermore, integration of gallium phosphide enables on-chip generation of self-referenced frequency combs. Next to nonlinear materials, the integration of very thin films is interesting for example for optomechanical devices that are based on the mechanical modes of thin membranes and their inclusion to the silicon photonics platforms. Lastly, the integration of 2D materials and quantum dots allows for e.g. single-photon sources, lasers and detectors on silicon photonics platforms.

According to example embodiments, the film comprises one or more of the following:
lithium niobate;
gallium phosphide;
lead zirconate titanate;
silicon;
silicon dioxide;
barium titanate;
barium titanate oxide;
lithium titanate;
lithium titanium oxide;
gallium nitride;
aluminium nitride;
titanium sapphire;
diamond;
one or more glasses doped with rare earths, such as for example one or more glasses to which one or more rare earth ions are added;
one or more 2D materials;
one or more layers comprising quantum dots;
one or more devices;
any suitable electro-optical material.

According to example embodiments, the support material comprises one of the following:
photoresist;
e-beam resist;
polymethyl methacrylate;
benzocyclobutene or divynilsiloxane bis-benzocyclobutene;
silicon;
amorphous silicon;
silicon dioxide;
silicon nitride;
aluminium oxide;
any suitable polymer.

According to example embodiments, the sacrificial layer comprises one or more of the following:
silicon;
silicon oxide;
silicon nitride;
one or more epitaxial layers, such as for example AlGaP when the film comprises GaP, AlGaAs when the film comprises GaAs, AlGaN when the film comprises GaN, etc.

According to example embodiments, the source substrate comprises one or more of the following:
lithium niobate;
silicon;
silicon dioxide;
silicon carbide;
germanium;
germanium-on-insulator;
III-V;
silicon-on-insulator;
any suitable substrate.

This way, the manufacturing of the source wafer of the present invention is compatible with existing manufacturing techniques developed for example for the complementary metal-oxide-semiconductor technology and processes. In other words, the manufacturing of the source wafer according to the present disclosure is CMOS compatible as present features and present process steps can be integrated therein without much additional effort. This reduces the complexity and the costs associated with manufacturing such a source wafer.

According to example embodiments, the target wafer comprises one or more of the following:
silicon nitride;
silicon-on-insulator;
one or more III-V materials;
lithium niobate;
sapphire;
generic integrated photonic platforms;
generic integrated electronic platforms;
any suitable substrate.

According to example embodiments, a distance from any point of the device coupon to an edge of a recess and a distance from any point of the device coupon to a periphery of the device coupon are smaller than 10 times a collapsing length for the film.

In the context of the present disclosure, it is relevant to consider a distance between two support structures and a distance between a support structure and an edge of the device coupon. A maximum distance between two support structures must be smaller than 10 times the collapsing length. A maximum distance between a support structure and an edge of the device coupon must be smaller than 10 times the collapsing length. In other words, a distance from any point of the device coupon to an edge of a recess and a distance from any point of the device coupon to a periphery of the device coupon are smaller than 10 times a collapsing length for the film.

According to example embodiments, the collapsing length is determined by the following method steps:
providing the film on top of the sacrificial layer on top of a test substrate;
defining a test device coupon in the film with a fixed predetermined width and extending over a length;
etching the sacrificial layer away between the test device coupon and the test substrate, thereby at least partially suspending the test device coupon above the test substrate and forming a cavity extending between the test device coupon and the test substrate; and
repeating the providing and the defining and the etching for different test device coupons of the fixed predetermined width and for increasing predetermined lengths for the test device coupons until a length for which a test device coupon first touches the test substrate along the fixed predetermined width, thereby determining the collapsing length.

The collapsing length is the smallest predetermined length for which the test device coupon touches the test substrate along the fixed predetermined width once the sacrificial layer has been etched away between the test device coupon and the test substrate. Preferably, the test device coupon preferably does not comprise any hole or any recess. The collapsing length of the film is larger than 3 μm. For example, the fixed predetermined width for the flexibility test is 100 μm. Alternatively, the fixed predetermined width for the flexibility test could be larger than 100 μm. The predetermined width for the flexibility test is fixed, i.e. all the test device coupons have the same width, but all the test device coupons have different lengths. Additionally, all the test device coupons are manufactured from the same film, and all the test device coupons therefore have the same thickness which is the thickness of the film. The flexibility test for the film starts with a first test device coupon with a fixed predetermined width of for example 100 μm and a length of for example 1 μm. The sacrificial layer is then etched away between this first test device coupon and the test substrate, thereby at least partially suspending the first test device coupon above the test substrate and forming a cavity extending between the first test device coupon and the test substrate. For the length of 1 μm, the first test device coupon for example does not touch the test substrate along the fixed predetermined width. The flexibility test then continues with forming a second test device coupon in the film on top of the sacrificial layer on top of the test substrate. The second test device coupon has the same fixed predetermined width than the first test device coupon, but the second test device coupon has a longer length than the first test device coupon. For example, a length of the second test device coupon is 2 μm. For the length of 2 μm, the second test device coupon for example does not touch the test substrate along the fixed predetermined width. The flexibility test then continues with forming a third test device coupon in the film on top of the sacrificial layer on top of the test substrate. The third test device coupon has the same fixed predetermined width than the first and the second test device coupons, but the third test device coupon has a longer length than the first and the second test device coupons. For example, a length of the third test device coupon is 3 μm. The steps described for the first, the second and the third test device coupons are repeated as new test device coupons are formed in the film, wherein the new test device coupons have the same fixed predetermined width but increasing lengths. After etching the sacrificial layer away, one test device coupon with the fixed predetermined width and a specific length will touch the test substrate along the while fixed predetermined width and not just at one or more single points. The length of this test device coupon is then the collapsing length for the film. The collapsing length for the film depends on or more of the following parameters: one or more material coefficients, such as for example Young's modulus, a thickness of the test device coupons, a thickness of the sacrificial layer, internal stress in the film and/or in the sacrificial layer, the use of critical point drying or not, etc.

The thickness of the film for the flexibility test is equal to the thickness of the film of the source wafer. The nature of the film for the flexibility test is identical to the nature of the film of the source wafer. The thickness of the sacrificial layer for the flexibility test is equal to the thickness of the sacrificial layer of the source wafer. The nature of the sacrificial layer for the flexibility test is identical to the nature of the sacrificial layer of the source wafer. The test substrate could be the same as the source substrate or could be different.

According to example embodiments, the method further comprises the steps of etching the sacrificial layer away:
at least partially between the designed breakable tethers and the source substrate, thereby forming breakable tethers; and
at least partially between the device coupon and the source substrate, thereby at least partially suspending the device coupon above the source substrate and forming a cavity extending at least partially between the device coupon and the source substrate and at least partially around the device coupon;
   and wherein the breakable tethers bridge the cavity, thereby securing the device coupon to the film.

This way, the device coupon is only secured to the film and consequently to the source substrate via the breakable tethers which are formed at the periphery of the device coupon. The designed breakable tethers are preferably designed within the plane of the film, more particularly within the plane of the device coupon. Preferably, a thickness of the breakable tethers corresponds to the thickness of the corresponding device coupon. The device coupon can easily be released from the source wafer upon fracture of the breakable tether. Indeed, each breakable tether comprises a breaking region. In the context of the present disclosure, a breaking region of a breakable tether corresponds to a region of the breakable tether which has been deliberately engineered to be weak and so preferentially break when the device coupon is lifted away from the substrate. In other words, the breaking regions of the breakable tethers have a lower shear strength than adjacent regions of the breakable tether and the breaking regions are engineered to fracture or break or cleave in a controller manner. A breakable tether according to the present disclosure may be formed in the film, i.e. may be made of the same material as the film. In other words, the breakable tether and its breaking region comprise the same constituents than the device coupon. Alternatively, the device coupon and the breakable tether do not comprise the same constituents. In other words, a breakable tether may be made of a different material than the device coupon, such as for example photoresist. Alternatively, the device coupon and the breaking regions do not comprise the same constituents, and the breaking regions and the rest of the breakable tethers do not comprise the same constituents. For example, the breaking regions of the breakable tethers are only a few um wide, while adjacent regions of the breakable tethers are tens of um wide. In the context of the present disclosure, the device coupon may be secured to the source substrate only by the breaking regions of the breakable tethers.

According to example embodiments, the support material is further provided on top of the device coupon.

Providing support material on top of the device coupon provides extra mechanical support to the device coupon, which improves its robustness and lowers the risk that the device coupon breaks when being picked-up from the source wafer. The device coupon is then encapsulated in support material. Providing support material on top of the device coupon further increases the stiffness of the device coupon, thereby resulting in larger collapsing lengths.

According to second example aspect of the present disclosure, there is provided a method for heterogeneously integrating a device coupon onto a target wafer via micro-transfer printing using the source wafer according to a first example aspect of the present disclosure, wherein the method comprising the steps of:
adhering the device coupon onto a stamp;
lifting the device coupon adhered onto the stamp away from the source substrate, thereby breaking one or more of the breakable tethers; and
pressing the device coupon onto the target wafer, thereby printing the device coupon onto the target wafer.

Based on the adhesion between a device coupon and a support structure and on the adhesion between the support structure and the source substrate, the support structures can be attached to the device coupon or to the source substrate. It is important that the adhesion of the stamp with the device coupon is larger than at least one of the previous two adhesions, such that the device coupon is reliably picked up from the source wafer, with or without the support structures. For example, the adhesion of the stamp to the device coupon is higher than the adhesion of the support structures to the substrate, but not higher than the adhesion of the support structures to the device coupon.

According to third example aspect of the present disclosure, there is provided a method for heterogeneously integrating a device coupon onto a target wafer via micro-transfer printing using the source wafer according to a first example aspect of the present disclosure, wherein the method comprising the steps of:
adhering the support material onto a stamp;
lifting the support material adhered onto the stamp and the device coupon away from the source substrate, thereby breaking one or more of the breakable tethers; and
pressing the device coupon onto the target wafer, thereby printing the device coupon onto the target wafer.

Based on the adhesion between a device coupon and a support structure and on the adhesion between the support structure and the source substrate, the support structures can be attached to the device coupon or to the source substrate. It is important that the adhesion of the device coupon with the stamp is larger than at least one of the previous two adhesions, such that the device coupon is reliably picked up from the source wafer, with or without the support structures. For example, the adhesion of the stamp to the support material is higher than the adhesion of the support structures to the substrate, but not higher than the adhesion of the support structures to the device coupon.

According to example embodiments, the support structures formed in the sacrificial recesses are lifted together with the device coupon away from the source substrate; and wherein the method further comprises the step of forming target recesses on the target wafer configured to host the support structures when the device coupon is pressed onto the target wafer.

In case the support structures are attached to the device coupon when the device coupon is picked up from the source substrate, one or more target recesses are manufactured in the target wafer such that during the printing process, the device coupon makes first contact with the target wafer. In other words, thanks to the target recesses, it is not the support structures which make first contact with the target wafer upon printing. Therefore, a depth of a target recess must be larger than a height of a support structure. A width of a target recess and a length of a target recess must also be larger than respectively a width and a length of a support structure, such that the support structure fits inside the target recess upon printing of the device coupon onto the target wafer. However, a target recess does not need to have the same shape as a support structure. The target wafer must comprise at least as many target recesses as there are support structures coupled to the device coupon. A position of the target recesses on the target wafer is defined such that the target recesses are coinciding vertically with the support structures.

According to example embodiments, the support structures formed in the sacrificial recesses remain on the source substrate when the device coupon is lifted away from the source substrate.

In case the support structures stay attached to the source substrate when the device coupon is picked up from the source substrate, the target wafer does not need to comprise target recesses.

According to example embodiments, the target wafer comprises one or more integrated optical structures.

For example, one or more waveguides and/or one or more integrated optical structures such as photonics structures are formed on the target wafer. The position for the printing of the device coupon on the target wafer is optimized to ensure a minimum alignment between the device coupon and the target wafer.

According to fourth example aspect of the present disclosure, there is provided a device manufactured using the method according to a second or a third example aspect of the present disclosure.

According to fifth example aspect of the present disclosure, there is provided a source wafer for heterogeneous integration through micro-transfer printing for integrated photonics systems and/or integrated electronics systems, the source wafer comprising:
a source substrate;
a film; wherein the film comprises at least one device coupon delimited by a periphery, wherein the device coupon comprises one or more recesses extending through the device coupon;
one or more designed breakable tethers at the periphery and configured to secure the device coupon to the film;
a sacrificial layer between the source substrate and the film, wherein the sacrificial layer comprises a sacrificial recess below one or more the recesses;
a support material filling at least some pairs of recesses and sacrificial recesses, thereby forming support structures for the device coupon in the device coupon and in the sacrificial layer;
   and wherein a distance from any point of the device coupon to an edge of a recess and a distance from any point of the device coupon to a periphery of the device coupon are smaller than 10 times a collapsing length for the film, wherein the collapsing length is determined by the following method steps:
providing the film on top of the sacrificial layer on top of a test substrate;
defining a test device coupon in the film with a fixed predetermined width and extending over a predetermined length;
etching the sacrificial layer away between the test device coupon and the test substrate, thereby suspending the test device coupon above the test substrate and forming a cavity extending between the test device coupon and the test substrate; and
repeating the defining and the etching for different test device coupons of the fixed predetermined width and for increasing predetermined lengths for the test device coupons until a predetermined length for which a test device coupon first touches the test substrate along the fixed predetermined width, thereby determining the collapsing length.

With the source wafer according to the present disclosure, a reliable high-yield heterogeneous integration of for example very flexible material thin films via micro-transfer printing is achieved. The present disclosure describes a source wafer that allows for suspending very thin films on source wafers, while keeping the large surface area that needs to be printed on a target wafer. With the source wafer according to the present disclosure, a device coupon is formed, which can for example demonstrate an aspect ratio of the device coupon for example exceeding 1000. Indeed, while the aspect ratio of the full device coupon still exceeds for example 1000, by forming support structures in the device coupon and under the device coupon which act like support pillars for the device coupon, the effective aspect ratio that matters for suspension of the device coupon is reduced significantly. Consequently, with the source wafer according to the present disclosure, it is much less challenging to suspend the device coupon, which leads to a high yield for the transfer-printing process. In other words, the support structures formed in the device coupon and under the device coupon of the source wafer according to the present disclosure increase the robustness of the device coupon. With the source wafer according to the present disclosure, particularly thanks to the support structures formed in the device coupon and under the device coupon, the adhesion between the device coupon and the source substrate of the source wafer is minimized, resulting in the ability to pick up the device coupon reliably from the source wafer. With the source wafer according to the present disclosure, the device coupon does not break when the device coupon is picked up from the source wafer, thereby reaching a reliable high yield for the transfer-printing of device coupons, such as for example of thin films. Finally, the source wafer according to the present disclosure allows changing the shape and/or the surface area of the device coupon without having to redevelop a process flow for forming and suspending the device coupon.

The source wafer according to the present disclosure can be used to manufacture device coupons which are for example made of very flexible materials with for example large surface areas, resulting in a high transfer-printing yield for their heterogeneous integration on photonic and electronic integrated circuits. Indeed, by placing support structures, such as pillar-like support structures, through the device coupons and under the device coupons, these device coupons no longer need to be suspended from side to side above the source wafer, but the device coupons are suspended from support structure to support structure on the source wafer. This distance to be suspended can be made much smaller by reducing a distance between two adjacent support structures, thereby significantly decreasing the effective aspect ratio. In contrast to prior art solutions which require a re-optimization of the whole layer stack without a guaranteed success, with the source wafer according to the present disclosure, there is no new optimization of the stiffness of the device coupon required when substantially changing the surface area or coupon shape in general, as it only comes down to optimizing a position of the support structures. For that reason, the source wafer according to the present disclosure shows a lot of potential for systems where the footprint cannot be reduced, such as for example ring resonators-limited by the bend radius, spirals or electro-optic modulators.

The current disclosure in addition also relates to a computer program comprising software code adapted to perform the method according to the present disclosure. The current disclosure further relates to a computer readable storage medium comprising the computer program according to the present disclosure. The current disclosure further relates to a computer readable storage medium comprising computer-executable instructions which, when executed by a computing system, perform the method according to the present disclosure.

### BRIEF DESCRIPTION OF THE DRAWINGS

Some example embodiments will now be described with reference to the accompanying drawings. The drawings depict cross-sections of source wafers and target wafers according to the present disclosure for clarity reasons. It is clear that the source wafers and the target wafers depicted in the accompanying drawings can have any shape and extend along any direction along the longitudinal direction 3 and/or the traverse direction 4, and/or a third direction 5 traverse to the longitudinal direction 3 and traverse to the traverse direction 4. The above directions are not repeated on all the accompanying drawings to keep the drawings simple.

FIGS. 1A and 1B schematically depict example embodiments of a source wafer according to the present disclosure.

FIG. 2A schematically depicts an example embodiment of a device coupon according to the present disclosure and comprising two recesses. FIGS. 2B and 2C schematically depict an example embodiment of a flexibility test for a film according to the present disclosure.

FIG. 3 schematically depicts an example embodiment of a source wafer according to the present disclosure.

FIG. 4 schematically depicts an example embodiment of a source wafer according to the present disclosure, wherein the sacrificial layer has been etched away and a device coupon is at least partially suspended above the source substrate.

FIG. 5 schematically depicts an example embodiment of a device coupon according to the present disclosure being lifted away from the source wafer.

FIG. 6 schematically depicts an example embodiment of a device coupon according to the present disclosure being printed onto a target wafer.

FIG. 7 schematically depicts an example embodiment of a device coupon according to the present disclosure being printed onto a target wafer.

FIG. 8 schematically depicts an example embodiment of a device coupon according to the present disclosure being printed onto a target wafer comprising one or more target recesses.

FIG. 9 schematically depicts an example embodiment of a device coupon according to the present disclosure being printed onto a target wafer comprising one or more target recesses.

FIG. 10 schematically depicts an example embodiment of a device coupon according to the present disclosure printed onto a target wafer comprising one or more target recesses.

FIG. 11 schematically depicts an example embodiment of a device coupon according to the present disclosure printed onto a target wafer comprising one or more target recesses.

FIG. 12 schematically depicts an example embodiment of a device coupon according to the present disclosure printed onto a target wafer.

FIG. 13 schematically depicts an example embodiment of a device coupon according to the present disclosure printed onto a target wafer.

### detailed description of embodiment(s)

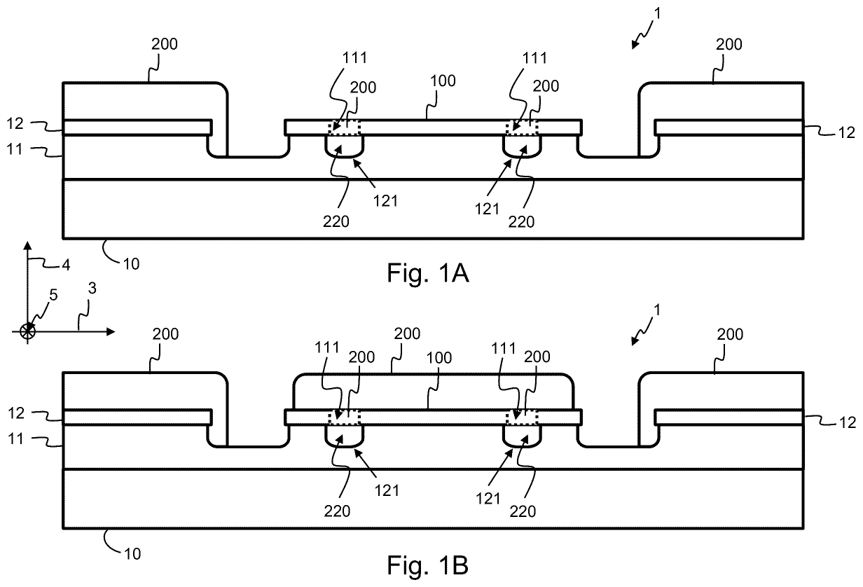

FIG. 1A schematically depicts an example embodiment of a source wafer 1 according to the present disclosure. A source wafer 1 comprises a source substrate 10, a sacrificial layer 11 on top of the source substrate 10, and a film 12 on top of the sacrificial layer 11. At least one device coupon 100 is formed in the film 12. One or more breakable tethers secure the device coupon 100 to the source substrate 10. The device coupon 100 comprises one or more recesses 111 extending through the device coupon 100, thereby exposing the sacrificial layer 11 through the recesses 111. The sacrificial layer 11 is etched away at least partially through one or more of the recesses 111, thereby forming one or more sacrificial recesses 121 in the sacrificial layer 11 between the device coupon 100 and the source substrate 10. A support material 200 is provided in at least some pairs of recesses 111 and sacrificial recesses 121, thereby forming support structures 220 for the device coupon 100 in the sacrificial layer 11.

FIG. 1B schematically depicts an example embodiment of a source wafer 1 according to the present disclosure. A source wafer 1 comprises a source substrate 10, a sacrificial layer 11 on top of the source substrate 10, and a film 12 on top of the sacrificial layer 11. At least one device coupon 100 is formed in the film 12. One or more breakable tethers secure the device coupon 100 to the source substrate 10. The device coupon 100 comprises one or more recesses 111 extending through the device coupon 100, thereby exposing the sacrificial layer 11 through the recesses 111. The sacrificial layer 11 is etched away at least partially through one or more of the recesses 111, thereby forming one or more sacrificial recesses 121 in the sacrificial layer 11 between the device coupon 100 and the source substrate 10. A support material 200 is provided in at least some pairs of recesses 111 and sacrificial recesses 121, thereby forming support structures 220 for the device coupon 100 in the sacrificial layer 11. The support material 200 is further provided on top of the device coupon 100.

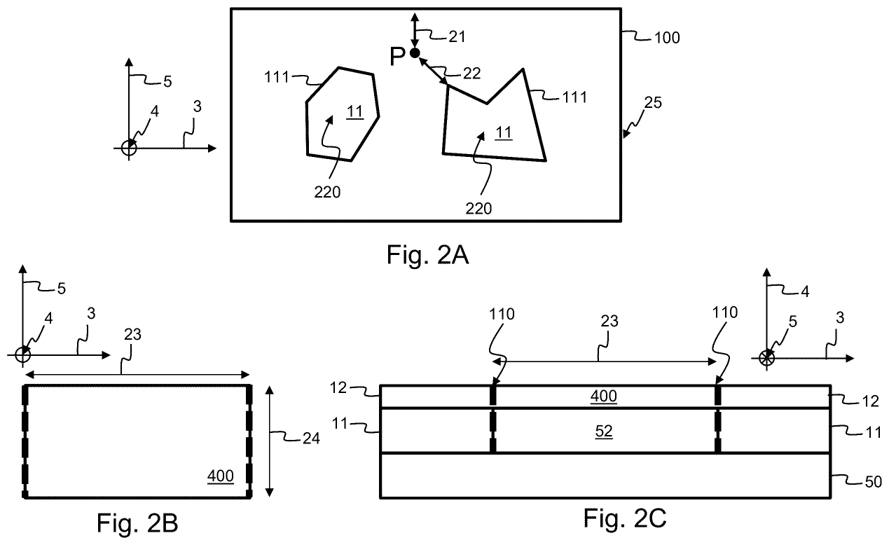

FIG. 2A schematically depicts an example embodiment of a design limitation for the support structures according to the present disclosure. A device coupon 100 is depicted in top view. The device coupon 100 comprises one or more recesses 111 which are etched completely through a thickness of the device coupon 100, thereby exposing the sacrificial layer 11 through the recesses 111. For each recess 111, a sacrificial recess is etched in the sacrificial layer 11. Point P in the device coupon 100 can be any point at the top surface of the device coupon 100. Alternatively, point P in the device coupon 100 can be any point defined through the thickness of the device coupon 100. Support structures 220 are formed out of a support material 200 in the pairs of recesses 111 and sacrificial recesses. A distance 21 from point P to a periphery 25 of the device coupon 100 is smaller than 10 times a collapsing length for the film in which the device coupon 100 is formed. A distance 22 from point P to an edge of a recess 111 of the device coupon 100 is smaller than 10 times a collapsing length for the film in which the device coupon 100 is formed.

FIG. 2B schematically depicts a top view of an example embodiment of a test device coupon 400 for a flexibility test for the film in which a device coupon is formed. FIG. 2C schematically depicts a side view of an example embodiment of a test device coupon 400 for a flexibility test for the film in which a device coupon is formed. For the flexibility test for a film, the film is provided on top of the sacrificial layer 11 on top of a test substrate 50. A test device coupon 400 is formed in the film 12 with a fixed predetermined width 24 and extends over a length 23. The sacrificial layer 11 is etched away between the test device coupon 400 and the test substrate 50, thereby suspending the test device coupon 400 above the test substrate 50 and forming a cavity 52 extending between the test device coupon 400 and the test substrate 50. This test is repeated for different test device coupons 400 with the fixed predetermined width and for increasing lengths for the test device coupons 400 until a length for which a test device coupon 400 first touches the test substrate 50 along the fixed predetermined width, thereby determining a collapsing length for the film.

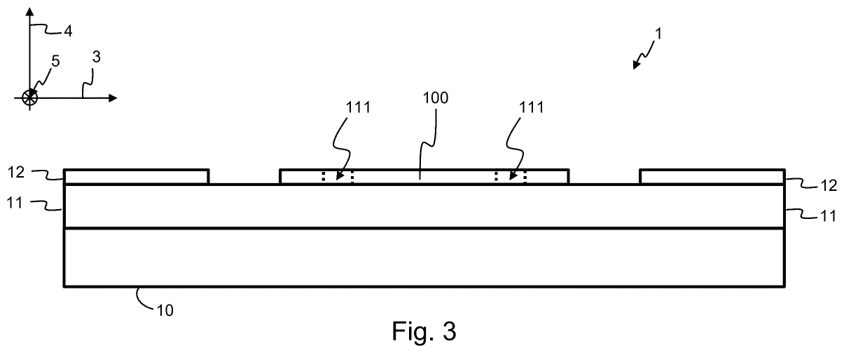

FIG. 3 schematically depicts an example embodiment of a source wafer 1 according to the present disclosure. FIG. 3 depicts a first step of a method for micro-transfer printing according to the present disclosure. A source wafer 1 comprises a source substrate 10, a sacrificial layer 11 on top of the source substrate 10, and a film 12 on top of the sacrificial layer 11. At least one device coupon 100 is formed in the film 12. One or more breakable tethers secure the device coupon 100 to the source substrate 10. The device coupon 100 comprises one or more recesses 111 extending through the device coupon 100, thereby exposing the sacrificial layer 11 through the recesses 111. The following method step is depicted in FIG. 1A or FIG. 1B and consists in etching the sacrificial layer 11 away through the recesses 111, thereby forming one or more sacrificial recesses 121 in the sacrificial layer 11.

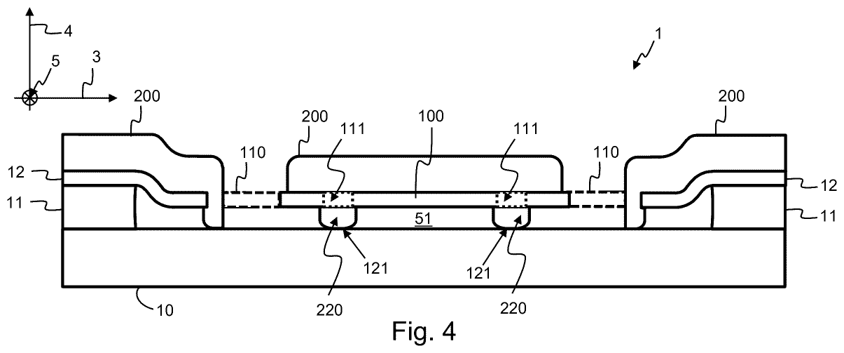

FIG. 4 schematically depicts the following step of a method for micro-transfer printing according to the present disclosure. Components having identical reference numbers than on previous figures fulfill the same function. A source wafer 1 comprises a source substrate 10, a sacrificial layer 11 on top of the source substrate 10, and a film 12 on top of the sacrificial layer 11. At least one device coupon 100 is formed in the film 12. One or more breakable tethers 110 secure the device coupon 100 to the source substrate 10 when the sacrificial layer 11 is etched away at least partially between designed breakable tethers 110 and the source substrate 10. The device coupon 100 comprises one or more recesses 111 extending through the device coupon 100, thereby exposing the sacrificial layer 11 through the recesses 111. The sacrificial layer 11 is etched away at least partially through one or more of the recesses 111, thereby forming one or more sacrificial recesses 121 in the sacrificial layer 11 between the device coupon 100 and the source substrate 10. A support material 200 is provided in at least some pairs of recesses 111 and sacrificial recesses 121, thereby forming support structures 220 for the device coupon 100 in the sacrificial layer 11. The sacrificial layer 11 is etched at least partially between the device coupon 100 and the source substrate 10, thereby suspending the device coupon 100 at least partially above the source substrate 10 and forming a cavity 51 extending at least partially between the device coupon 100 and the source substrate 10 and at least partially around the device coupon 100. The breakable tethers 110 bridge the cavity 51.

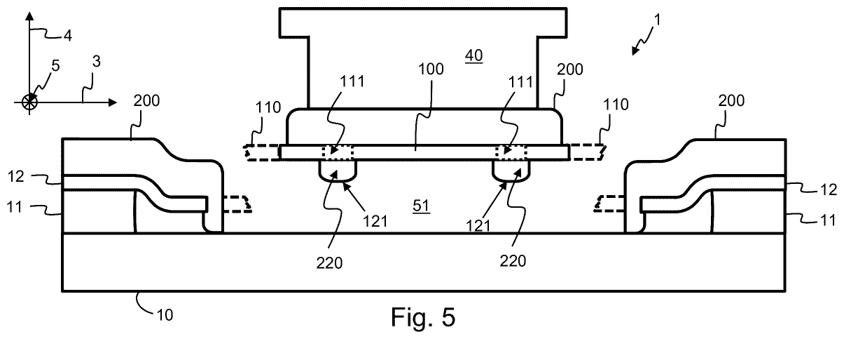

FIG. 5 schematically depicts the following step of a method for micro-transfer printing according to the present disclosure. Components having identical reference numbers than on previous figures fulfill the same function. A source wafer 1 comprises a source substrate 10, a sacrificial layer 11 on top of the source substrate 10, and a film 12 on top of the sacrificial layer 11. At least one device coupon 100 is formed in the film 12. One or more breakable tethers 110 secure the device coupon 100 to the source substrate 10 when the sacrificial layer 11 is etched away at least partially between designed breakable tethers 110 and the source substrate 10. The device coupon 100 comprises one or more recesses 111 extending through the device coupon 100, thereby exposing the sacrificial layer 11 through the recesses 111. The sacrificial layer 11 is etched away at least partially through one or more of the recesses 111, thereby forming one or more sacrificial recesses 121 in the sacrificial layer 11 between the device coupon 100 and the source substrate 10. A support material 200 is provided in at least some pairs of recesses 111 and sacrificial recesses 121, thereby forming support structures 220 for the device coupon 100 in the sacrificial layer 11. The sacrificial layer 11 is etched at least partially between the device coupon 100 and the source substrate 10, thereby suspending the device coupon 100 at least partially above the source substrate 10 and forming a cavity 51 extending at least partially between the device coupon 100 and the source substrate 10 and at least partially around the device coupon 100. The breakable tethers 110 bridge the cavity 51. A stamp 40 is adhered onto the support material 200 provided on top of the device coupon 100. The support material 200 adhered onto the stamp 40 and the device coupon 100 are lifted away from the source substrate 10, thereby breaking one or more of the breakable tethers 110. A broken breakable tether 110 comprises a first portion remaining coupled to the device coupon 100 and a second portion remaining coupled to the film 12. According to an alternative embodiment, no support material 200 is provided on top of the device coupon 100. A stamp 40 is adhered onto the device coupon 100. The device coupon 100 is lifted away from the source substrate 10, thereby breaking one or more of the breakable tethers 110. As depicted on FIG. 5, the support structures 220 formed in the sacrificial recesses 121 are lifted together with the device coupon 100 away from the source substrate 10. According to an alternative embodiment, the support structures 220 formed in the sacrificial recesses 121 remain on the source substrate 10 when the device coupon 100 is lifted away from the source substrate 10.

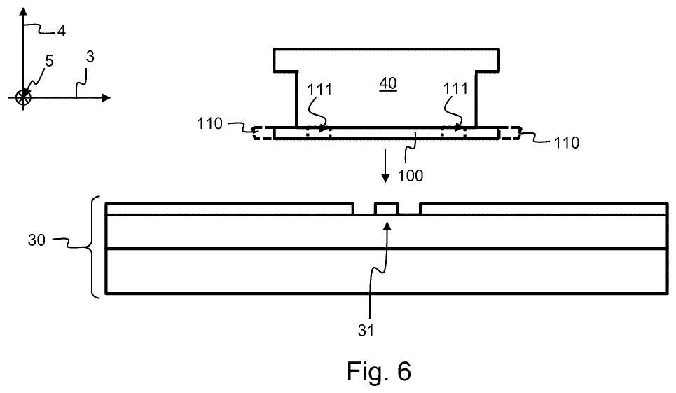

FIG. 6 schematically depicts the following step of a method for micro-transfer printing according to the present disclosure. Components having identical reference numbers than on previous figures fulfill the same function. A stamp 40 is adhered onto the device coupon 100. The device coupon 100 has been lifted away from a source substrate, thereby breaking one or more breakable tethers 110. A broken breakable tether 110 comprises a first portion remaining coupled to the device coupon 100 and a second portion remaining coupled to the film on the source wafer. The support structures 220 formed in the sacrificial recesses remain on the source substrate when the device coupon 100 is lifted away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31.

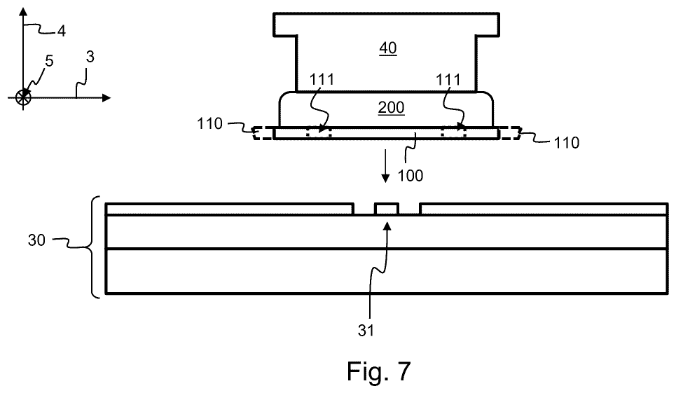

FIG. 7 schematically depicts the following step of a method for micro-transfer printing according to the present disclosure. Components having identical reference numbers than on previous figures fulfill the same function. A stamp 40 is adhered onto the support material 200 provided on top of the device coupon 100. The support material 200 adhered onto the stamp 40 and the device coupon 100 are lifted away from the source substrate, thereby breaking one or more of the breakable tethers 110. A broken breakable tether 110 comprises a first portion remaining coupled to the device coupon 100 and a second portion remaining coupled to the film on the source wafer. The support structures 220 formed in the sacrificial recesses remain on the source substrate when the device coupon 100 is lifted away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31.

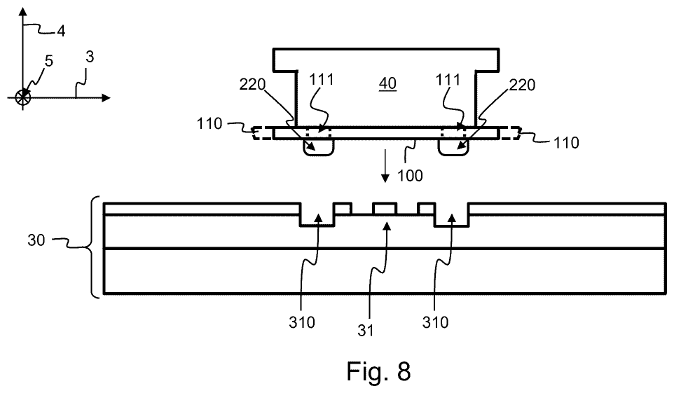

FIG. 8 schematically depicts an alternative embodiment of a method step of a method for micro-transfer printing according to the present disclosure. Components having identical reference numbers than on previous figures fulfill the same function. A stamp 40 is adhered onto the device coupon 100. The device coupon 100 has been lifted away from a source substrate, thereby breaking one or more breakable tethers 110. A broken breakable tether 110 comprises a first portion remaining coupled to the device coupon 100 and a second portion remaining coupled to the film on the source wafer. The support structures 220 formed in the sacrificial recesses are lifted together with the device coupon 100 away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31. The target wafer 30 further comprises one or more target recesses 310 formed to host the support structures 220 when the device coupon 100 is pressed onto the target wafer 30.

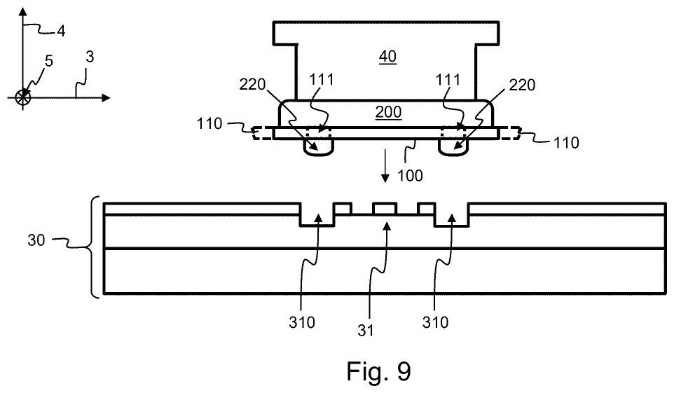

FIG. 9 schematically depicts an alternative embodiment of a method step of a method for micro-transfer printing according to the present disclosure. Components having identical reference numbers than on previous figures fulfill the same function. A stamp 40 is adhered onto the support material 200 provided on top of the device coupon 100. The support material 200 adhered onto the stamp 40 and the device coupon 100 are lifted away from the source substrate, thereby breaking one or more of the breakable tethers 110. A broken breakable tether 110 comprises a first portion remaining coupled to the device coupon 100 and a second portion remaining coupled to the film on the source wafer. The support structures 220 formed in the sacrificial recesses are lifted together with the device coupon 100 away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31. The target wafer 30 further comprises one or more target recesses 310 formed to host the support structures 220 when the device coupon 100 is pressed onto the target wafer 30.

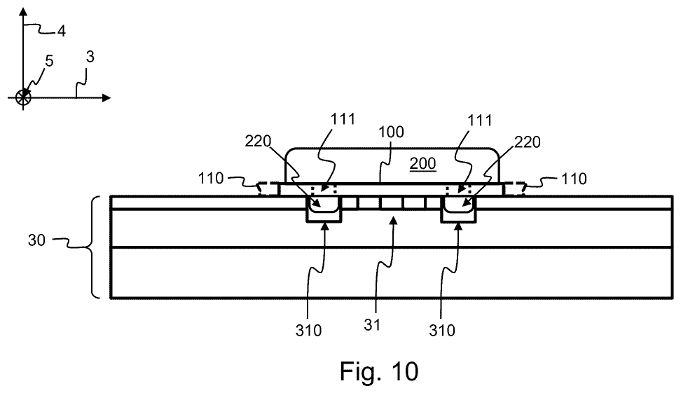

FIG. 10 schematically depicts the following step of a method for micro-transfer printing according to the present disclosure. Components having identical reference numbers than on previous figures fulfill the same function. Support material 200 is provided on top of the device coupon 100. The support material 200 adhered onto a stamp and the device coupon 100 are lifted away from the source substrate, thereby breaking one or more of the breakable tethers 110. A broken breakable tether 110 comprises a first portion remaining coupled to the device coupon 100 and a second portion remaining coupled to the film on the source wafer. The support structures 220 formed in the sacrificial recesses are lifted together with the device coupon 100 away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31. The target wafer 30 further comprises one or more target recesses 310 formed to host the support structures 220 when the device coupon 100 is pressed onto the target wafer 30.

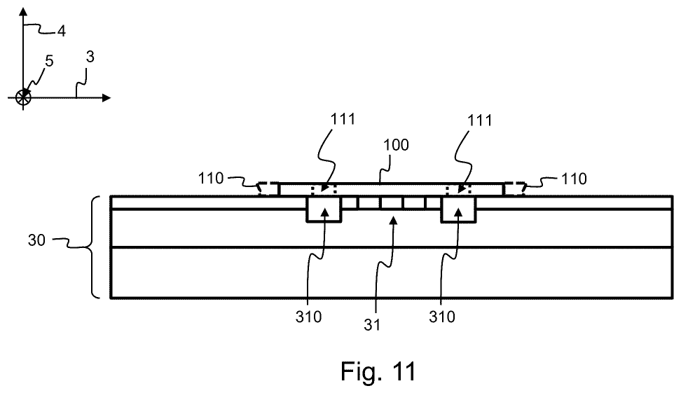

FIG. 11 schematically depicts the following step of a method for micro-transfer printing according to the present disclosure. Components having identical reference numbers than on previous figures fulfill the same function. The support material 200 of FIG. 10 is stripped away from the assembly formed by the device coupon 100 and the target wafer 30, i.e. is stripped away from the recesses 111, from the target recesses 310 and optionally from above the device coupon 100.

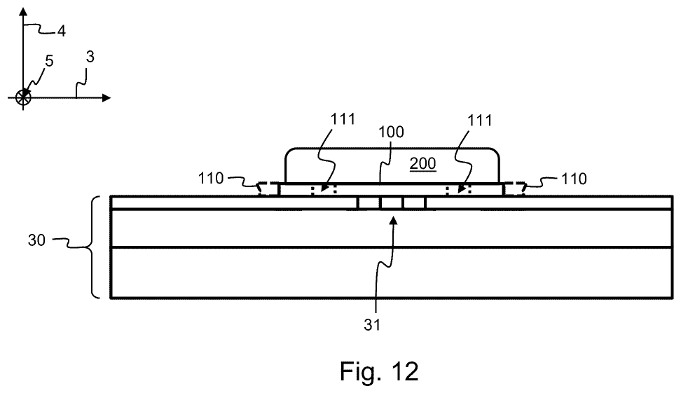

FIG. 12 schematically depicts an alternative embodiment of a method step of a method for micro-transfer printing according to the present disclosure. Components having identical reference numbers than on previous figures fulfill the same function. Support material 200 is provided on top of the device coupon 100. The support material 200 adhered onto a stamp and the device coupon 100 are lifted away from the source substrate, thereby breaking one or more of the breakable tethers 110. A broken breakable tether 110 comprises a first portion remaining coupled to the device coupon 100 and a second portion remaining coupled to the film on the source wafer. The support structures 220 formed in the sacrificial recesses remain on the source substrate when the device coupon 100 is lifted away from the source substrate. The device coupon 100 is pressed onto a target wafer 30, thereby printing the device coupon 100 onto the target wafer 30. The target wafer 30 for example comprises several layers and for example a target substrate. The target wafer 30 for example comprises one or more integrated optical structures 31.

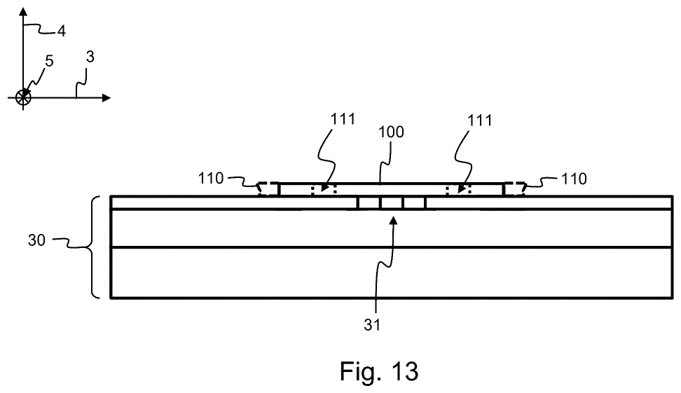

FIG. 13 schematically depicts the following step of a method for micro-transfer printing according to the present disclosure. Components having identical reference numbers than on previous figures fulfill the same function. The support material 200 of FIG. 10 is stripped away from the assembly formed by the device coupon 100 and the target wafer 30, i.e. is stripped away from the recesses 111 and optionally from above the device coupon 100.

Although the present invention has been illustrated by reference to specific embodiments, it will be apparent to those skilled in the art that the invention is not limited to the details of the foregoing illustrative embodiments, and that the present invention may be embodied with various changes and modifications without departing from the scope thereof. The present embodiments are therefore to be considered in all respects as illustrative and not restrictive, the scope of the invention being indicated by the appended claims rather than by the foregoing description, and all changes which come within the scope of the claims are therefore intended to be embraced therein.

It will furthermore be understood by the reader of this patent application that the words “comprising” or “comprise” do not exclude other elements or steps, that the words “a” or “an” do not exclude a plurality, and that a single element, such as a computer system, a processor, or another integrated unit may fulfil the functions of several means recited in the claims. Any reference signs in the claims shall not be construed as limiting the respective claims concerned. The terms “first”, “second”, third“, “a”, “b”, “c”, and the like, when used in the description or in the claims are introduced to distinguish between similar elements or steps and are not necessarily describing a sequential or chronological order. Similarly, the terms “top”, “bottom”, “over”, “under”, and the like are introduced for descriptive purposes and not necessarily to denote relative positions. It is to be understood that the terms so used are interchangeable under appropriate circumstances and embodiments of the invention can operate according to the present invention in other sequences, or in orientations different from the one(s) described or illustrated above.

1. A method for forming a device coupon for heterogeneous integration through micro-transfer printing for integrated photonics systems and/or integrated electronics systems, said method comprising the steps of:
providing a source wafer comprising:
a source substrate ;
a sacrificial layer on top of said source substrate; and
a film on top of said sacrificial layer;
forming at least one device coupon in said film, wherein a device coupon is delimited by a periphery;
designing one or more designed breakable tethers at said periphery, said designed breakable tethers being configured to secure said device coupon to said film;
etching one or more recesses in said device coupon, said recesses extending through said device coupon, thereby exposing said sacrificial layer;
partially etching said sacrificial layer away at least through one or more of said recesses, thereby forming one or more sacrificial recesses in said sacrificial layer between said device coupon and said source substrate; and
filling at least some pairs of recesses and sacrificial recesses with a support material, thereby forming support structures for said device coupon (100) in said device coupon and in said sacrificial layer.

2. The method according to claim 1, wherein a distance from any point of said device coupon to an edge of a recess and a distance from any point of said device coupon to said periphery of said device coupon are smaller than ten times a collapsing length for said film.

3. The method according to claim 2, wherein said collapsing length is determined by the following method steps:
providing said film on top of said sacrificial layer on top of a test substrate;
defining a test device coupon in said film with a fixed predetermined width and extending over a length;
etching said sacrificial layer away between said test device coupon and said test substrate, thereby suspending said test device coupon above said test substrate and forming a cavity extending between said test device coupon and said test substrate; and
repeating said providing and said defining and said etching for different test device coupons of said fixed predetermined width and for increasing predetermined lengths for said test device coupons until a length for which a test device coupon first touches said test substrate along said fixed predetermined width, thereby determining said collapsing length.

4. The method according to claim 1, wherein said method further comprises the steps of etching said sacrificial layer away:
at least partially between said designed breakable tethers and said source substrate, thereby forming breakable tethers; and
at least partially between said device coupon and said source substrate, thereby at least partially suspending said device coupon above said source substrate and forming a cavity extending at least partially between said device coupon and said source substrate and at least partially around said device coupon;
and wherein said breakable tethers bridge said cavity, thereby securing said device coupon to said film.

5. The method according to claim 1, wherein said support material is further provided on top of said device coupon.

6. A method for heterogeneously integrating a device coupon onto a target wafer via micro-transfer printing using the source wafer according to claim 4, wherein said method comprising the steps of:
adhering said device coupon onto a stamp;
lifting said device coupon adhered onto said stamp away from said source substrate, thereby breaking one or more of said breakable tethers; and
pressing said device coupon onto said target wafer, thereby printing said device coupon onto said target wafer.

7. A method for heterogeneously integrating a device coupon onto a target wafer via micro-transfer printing using the source wafer according to claim 4, wherein said method comprising the steps of:
adhering said support material onto a stamp;
lifting said support material adhered onto said stamp and said device coupon away from said source substrate, thereby breaking one or more of said breakable tethers; and
pressing said device coupon onto said target wafer, thereby printing said device coupon onto said target wafer.

8. The method according to claim 6, wherein said support structures formed in said sacrificial recesses are lifted together with said device coupon away from said source substrate; and wherein said method further comprises the step of forming target recesses on said target wafer configured to host said support structures when said device coupon is pressed onto said target wafer.

9. The method according to claim 6, wherein said support structures formed in said sacrificial recesses remain on said source substrate when said device coupon is lifted away from said source substrate.

10. The method according to claim 6, wherein said target wafer comprises one or more integrated optical structures.

11. A device manufactured using the method of claim 6.

12. A source wafer for heterogeneous integration through micro-transfer printing for integrated photonics systems and/or integrated electronics systems, said source wafer comprising:
a source substrate;
a film; wherein said film comprises at least one device coupon delimited by a periphery, wherein said device coupon comprises one or more recesses extending through said device coupon;
one or more designed breakable tethers at said periphery and configured to secure said device coupon to said film;
a sacrificial layer between said source substrate and said film, wherein said sacrificial layer comprises a sacrificial recess below one or more said recesses;
a support material filling at least some pairs of recesses and sacrificial recesses, thereby forming support structures for said device coupon in said device coupon and in said sacrificial layer;
and wherein a distance from any point of said device coupon to an edge of a recess and a distance from any point of said device coupon to said periphery of said device coupon are smaller than ten times a collapsing length for said film, wherein said collapsing length is determined by the following method steps:
providing said film on top of said sacrificial layer on top of a test substrate;
defining a test device coupon in said film with a fixed predetermined width and extending over a predetermined length;
etching said sacrificial layer away between said test device coupon and said test substrate, thereby suspending said test device coupon above said test substrate and forming a cavity extending between said test device coupon and said test substrate; and
repeating said defining and said etching for different test device coupons of said fixed predetermined width and for increasing predetermined lengths for said test device coupons until a predetermined length for which a test device coupon first touches said test substrate along said fixed predetermined width, thereby determining said collapsing length.
